(19) United States
(12) Patent Application Publication
(10) Pub. No.: US 2006/0239476 A1
(43) Pub. Date: Oct. 26, 2006

(54) Biasing circuit for sound source amplifier

(75) Inventor: Shih-Hua Chang, Taipei (TW)

Correspondence Address: Haverstock & Owens LLP, 162 Nolth Wolfe Road, Sunnyvale, CA, 94086, US

(73) Assignee: Samhop Microelectronics Corp.

(21) Appl. No.: 11/253,443

(22) Filed: Oct. 18, 2005

(30) Foreign Application Priority Data
Apr. 26, 2005 (TW) 94113327

(51) Int. Cl. H03F 21/00

(52) U.S. Cl. 381/120

(57) ABSTRACT

A biasing circuit for a sound source amplifier is provided. The sound source amplifier has an output terminal electrically connected to a first capacitor with a charging velocity. The biasing circuit includes a switch having a turning-on velocity and a first terminal electrically connected to a first voltage source providing a relatively high voltage, a voltage-dividing circuit having a first terminal electrically connected to a second terminal of the switch and a second terminal electrically connected to a second voltage source providing a relatively low voltage, an operational amplifier having an output terminal electrically connected to a controlling terminal of the switch, a noninverting input terminal and an inverting input terminal coupled to the voltage-dividing circuit, and a second capacitor having a first terminal coupled to the inverting input terminal and the voltage-dividing circuit, and a second terminal electrically connected to the second voltage source, wherein the charging velocity is controlled by adjusting the turning-on velocity of the switch with the operational amplifier while the sound source amplifier is turned on.

### FIELD OF THE INVENTION

The present invention relates to a biasing circuit, especially to a biasing circuit for a sound source amplifier.

### BACKGROUND OF THE INVENTION

In most applications of electrical circuits, a fixed bias is often used as a DC operating point for an amplifier. Similarly, a biasing circuit is also needful for the implementation of a sound source amplifier.

Please refer to FIG. 1, which is a circuit diagram showing a sound source amplifier according to the prior art. The sound source amplifier 10 is composed of two resistors RI and RF, an amplifier 30 and a biasing circuit 20. An input terminal of the sound source amplifier 10 is connected to a capacitor CI and a sound input signal source AC. An output terminal of the sound source amplifier 10 is connected to another capacitor CC and an earphone (or a speaker) represented by a resistor RL.

According to the prior art showed in FIG. 2, the biasing circuit 20 is controlled by voltage-dividing resistors to provide a non-negative feedback DC bias VB with a voltage of V_{DD}/2.

Please refer to FIG. 2, which is a circuit diagram showing a biasing circuit for a sound source amplifier according to the prior art. The biasing circuit 20 is composed of a switch M1 connected to a power source PWR, three equivalent resistors R1˜R3 and an equivalent capacitor C1. The DC bias VB is provided at a node between the equivalent resistor R3 and the equivalent capacitor C1.

In FIG. 1, an additional capacitor CC is connected between the output terminal of the sound source amplifier 10 and the earphone RL so that the direct current is isolated and the power loss is decreased. Meanwhile, the DC bias VB outputted from the biasing circuit 20 is produced through the voltage-dividing effect of the equivalent resistors R1˜R3. However, while the sound source amplifier 10 is turned on, an extremely fast charging velocity of the equivalent capacitor C1 leads to a large current passing through the capacitor CC connected to the output terminal of the sound source amplifier 10. Therefore, a high-frequency noise occurs at the load (earphone) RL when a system including the sound source amplifier 10 is turned on.

Please refer to FIG. 3, which is a timing diagram showing the output terminal voltage VO and the load voltage VL of the sound source amplifier 10 shown in FIG. 1, with the biasing circuit 20 shown in FIG. 2. In FIG. 3, it is known that the foregoing high-frequency noise makes the voltage value at the load RL rise from 0 to 320-360 mV or so in 25 ms. That is to say, a user must endure a high-frequency noise in the earphone while turning on the system. Accordingly, the performance of the sound source amplifier 10 is seriously affected due to the above drawback.

To eliminate the high-frequency noise, the equivalent resistor of larger resistance or the capacitor C1 of larger capacitance is utilized for increasing and smoothing the charging time of the capacitor C1 in the prior art. However, it leads to the higher cost and the longer initialization time.

### SUMMARY OF THE INVENTION

For overcoming the mentioned drawbacks in the prior art, the present invention provides a biasing circuit for a sound source amplifier. An additional operational amplifier is added to the biasing circuit of the prior art to control the switch therein and make it be turned on at a slower velocity. The charging velocity of the capacitor connected to the output terminal of the sound source amplifier is therefore able to be under control. According to the present invention, the high-frequency noise during the initialization time of the system is eliminated and the production cost thereof is reduced.

According to one aspect of the present invention, a biasing circuit for a sound source amplifier is provided. The sound source amplifier has an output terminal electrically connected to a first capacitor with a charging velocity. The biasing circuit includes a switch having a turning-on velocity and a first terminal electrically connected to a first voltage source providing a relatively high voltage, a voltage-dividing circuit having a first terminal electrically connected to a second terminal of the switch and a second terminal electrically connected to a second voltage source providing a relatively low voltage, an operational amplifier having an output terminal electrically connected to a controlling terminal of the switch, a noninverting input terminal and an inverting input terminal coupled to the voltage-dividing circuit, and a second capacitor having a first terminal coupled to the inverting input terminal and the voltage-dividing circuit, and a second terminal electrically connected to the second voltage source, wherein the charging velocity is controlled by adjusting the turning-on velocity of the switch with the operational amplifier while the sound source amplifier is turned on.

Preferably, the sound source amplifier has an input terminal electrically connected to a sound source input circuit.

Preferably, the sound source input circuit includes a third capacitor connected to a sound input signal source in series.

Preferably, the voltage-dividing circuit is used for providing a DC biased voltage to the sound source amplifier.

Preferably, the first capacitor is electrically connected to a load and the load is a headphone.

Preferably, the first capacitor is electrically connected to a load and the load is a speaker.

Preferably, the switch is a MOSFET.

Preferably, the first voltage source is a DC voltage source and the second voltage source is grounded.

Preferably, the first voltage source is a DC voltage source and the relatively low voltage is a negative voltage.

Preferably, the voltage-dividing circuit includes a plurality of equivalent resistors.

Preferably, the voltage-dividing circuit includes four resistors which are connected to one another in series.

According to another aspect of the present invention, a biasing circuit for a sound source amplifier is provided. The sound source amplifier has an output terminal electrically connected to a first capacitor with a charging velocity. The biasing circuit includes a switch having a first terminal electrically connected to a first voltage source providing a relatively high voltage, an operational amplifier having an output terminal electrically connected to a controlling terminal of the switch, a first, a second, a third and a fourth resistors, wherein the first resistor has a first terminal electrically connected to a second terminal of the switch, the first resistor has a second terminal sequentially connected to the second resistor, the third resistor and a second voltage source providing a relatively low voltage in series, a first terminal of the fourth resistor is electrically connected to a node between the first resistor and the second resistor, a second terminal of the fourth resistor is electrically connected to an inverting input terminal of the operational amplifier and a second capacitor, and a noninverting input terminal of the operational amplifier is electrically connected to a node between the second resistor and the third resistor, and a second capacitor having a first terminal coupled to the inverting input terminal and the voltage-dividing circuit, and a second terminal electrically connected to the second voltage source, wherein the charging velocity is controlled by adjusting a turning-on velocity of the switch with the operational amplifier while the sound source amplifier is turned on.

Preferably, the sound source amplifier has an input terminal electrically connected to a sound source input circuit.

Preferably, the sound source input circuit includes a third capacitor connected to a sound input signal source in series.

Preferably, the voltage-dividing circuit is used for providing a DC biased voltage to the sound source amplifier.

Preferably, the first capacitor is electrically connected to a load and the load is a headphone.

Preferably, the first capacitor is electrically connected to a load and the load is a speaker.

Preferably, the switch is a MOSFET.

Preferably, the first voltage source is a DC voltage source and the second voltage source is grounded.

Preferably, the first voltage source is a DC voltage source and the relatively low voltage is a negative voltage.

The foregoing and other features and advantages of the present invention will be more clearly understood through the following descriptions with reference to the drawings, wherein:

### BRIEF DESCRIPTION OF THE DRAWINGS

FIG. 1 is a circuit diagram showing a sound source amplifier according to the prior art;

FIG. 2 is a circuit diagram showing a biasing circuit for a sound source amplifier according to the prior art;

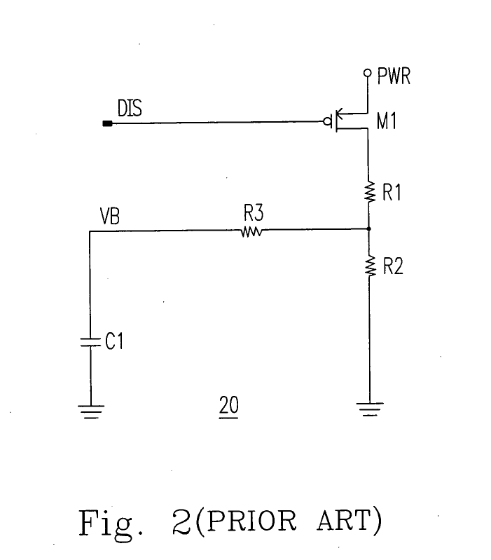

FIG. 3 is a timing diagram showing the output terminal voltage VO and the load voltage VL of the sound source amplifier 10 shown in FIG. 1, with the biasing circuit 20 shown in FIG. 2;

FIG. 4 is a circuit diagram showing a biasing circuit for a sound source amplifier according to a preferable embodiment of the present invention; and

FIG. 5 is a timing diagram showing the output terminal voltage VO and the load voltage VL of the sound source amplifier 10 shown in FIG. 1, with the biasing circuit 40 shown in FIG. 4.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

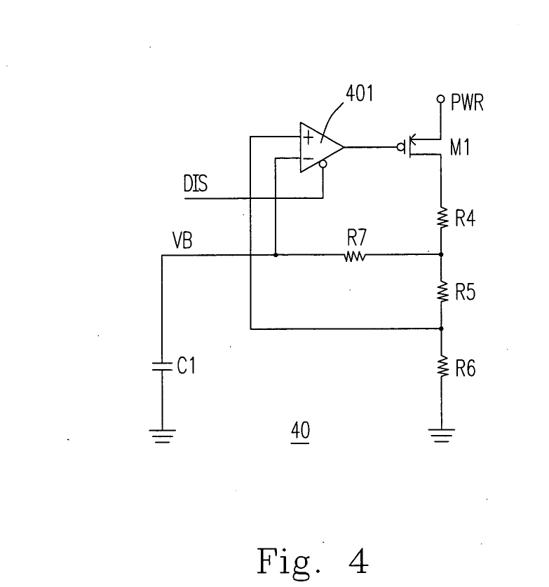

Please refer to FIG. 4, which is a circuit diagram showing a biasing circuit for a sound source amplifier according to a preferable embodiment of the present invention. The biasing circuit 40 is composed of a MOSFET switch M1, a voltage-dividing circuit composed of a plurality of resistors, e.g. the resistors R4˜R7 shown in FIG. 4, an operational amplifier 401 and an equivalent capacitor C1. The voltage VB is decided by the dividing voltages of the equivalent resistors.

In FIG. 4, an emitter terminal of the MOSFET switch M1 is connected to a DC voltage source PWR, a drain terminal of the MOSFET switch M1 is connected to the first resistor R4, and a gate terminal of the MOSFET switch M1 is connected to an output terminal of the operational amplifier. Besides, the first resistor R4, the second resistor R5 and the third resistor R6 are connected to one another in series and then connected to the ground. One terminal of the fourth resistor R7 is connected to a node between the first resistor R4 and the second resistor R5, and the other terminal of the fourth resistor R7 is connected to an inverting input terminal of the operational amplifier 401, represented by an minus sign, and the equivalent capacitor C1. An noninverting input terminal of the operational amplifier 401, represented by an plus sign, is connected to a node between the second resistor R5 and the third resistor R6.

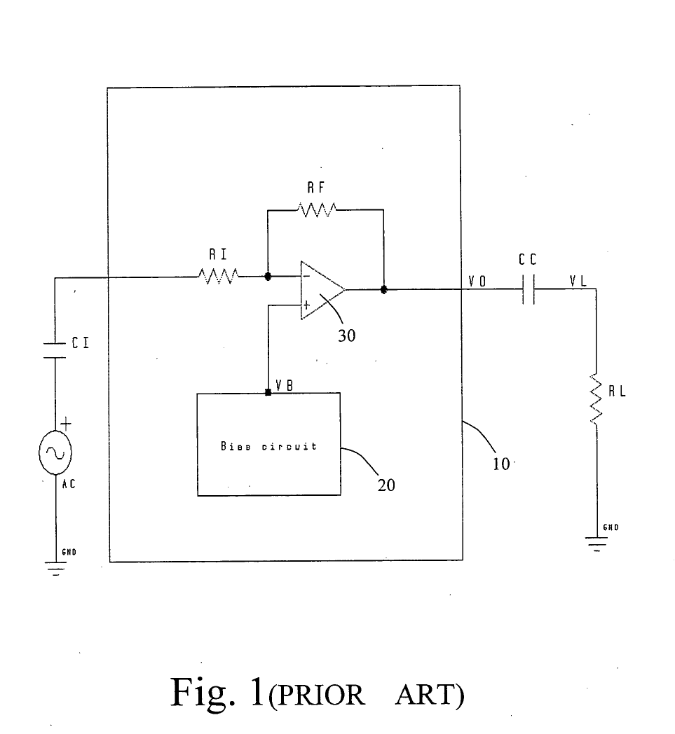

As the biasing circuit 40 of the present invention is an improvement on the traditional one of the mentioned sound source amplifier, the sound source amplifier 10 in FIG. 1 is also applicable to the present invention.

In FIG. 1, the input terminal of the sound source amplifier 10 is connected to the capacitor CI and the sound input signal source AC, and the output terminal of the sound source amplifier 10 is connected to the capacitor CC and the load RL. The technical feature of the present invention is the introduction of the operational amplifier 401. While the sound source amplifier 10 is turned on, the operational amplifier 401 is able to modulate the turning-on velocity of the MOSFET switch M1 so that the charging time of the capacitor C1 is increased and the charging velocity thereof is smoothed. This eliminates the effect of the high-frequency noise during the initialization process in the prior art.

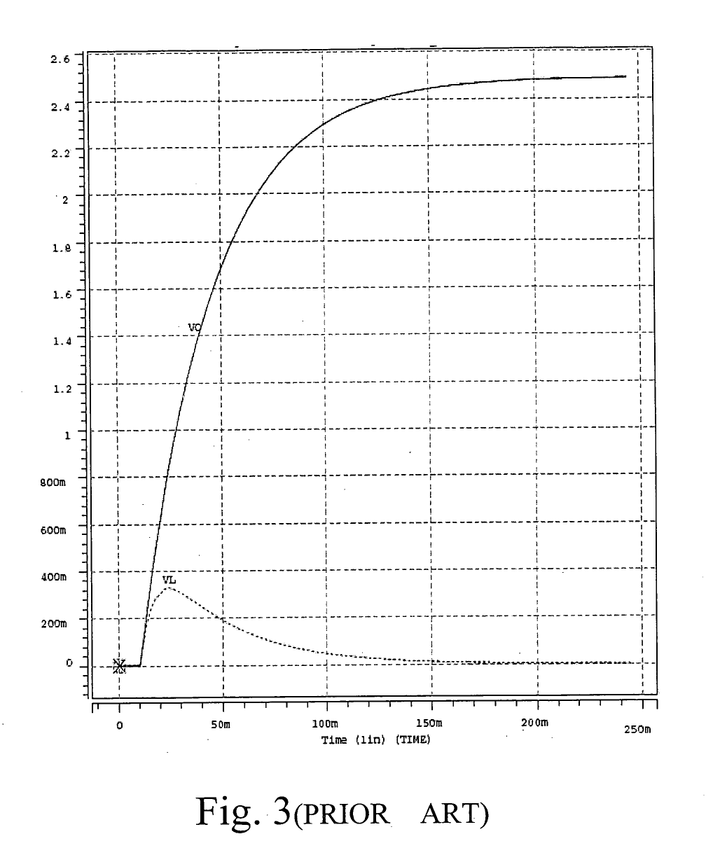

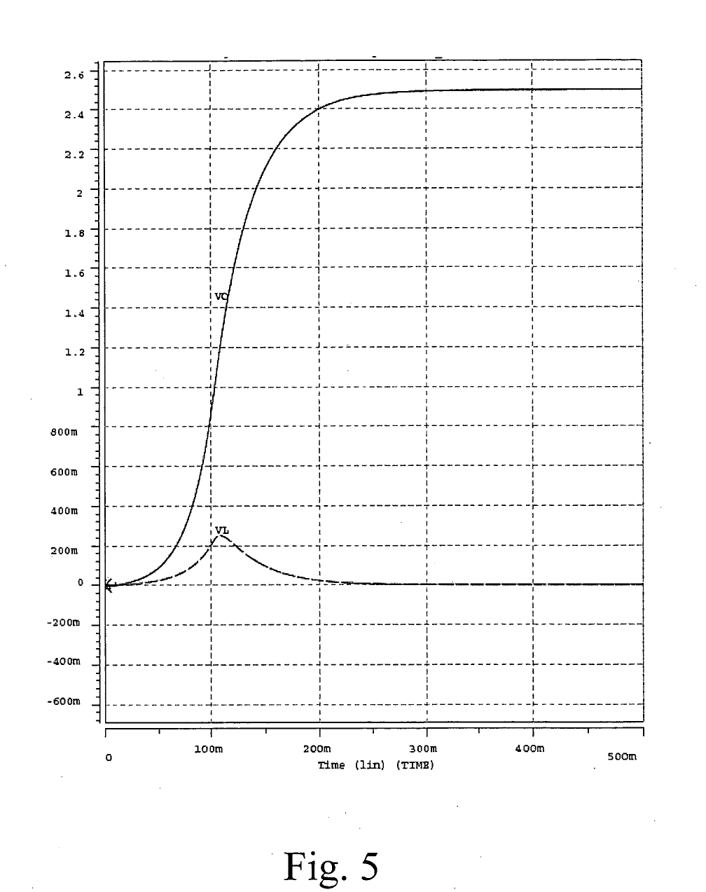

Please refer to FIG. 5, which is a timing diagram showing the output terminal voltage VO and the load voltage VL of the sound source amplifier 10 shown in FIG. 1, with the biasing circuit 40 shown in FIG. 4. The VO curve represents the variation of the voltage at the output terminal of the sound source amplifier 10, and the VL curve represents the variation of the voltage at the upper terminal of the load RL. As shown in FIG. 5, the VO curve takes 100 ms to reach 800 mV, while a relatively peak of the VL curve is about 240 mV. In FIG. 3, however, the VO curve takes 25 ms to reach 800 mV. Besides, the relatively peak of the VL curve in FIG. 3 is almost 320 mV.

When the biasing circuit 40 of the present invention is applied in the traditional sound source amplifier 10, the switching operation of the switch M1 is controlled by the operational amplifier 401 of the biasing circuit 40 so that the charging velocity of the capacitor C1 is modulated from a slow velocity to a fast one. The signal outputted to the load RL becomes the VL curve as shown in FIG. 5, which falls in the low frequency range that humans can not hear. Therefore, without increase of the capacitance of the capacitor C1 and the resistance of the equivalent voltage-dividing resistors R4˜R7, the biasing circuit 40 of the present invention effectively eliminate the high-frequency noise while the sound source amplifier 10 is turned on. Moreover, the production cost is reduced as well.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A biasing circuit for a sound source amplifier, wherein said sound source amplifier having an output terminal electrically connected to a first capacitor with a charging velocity, comprising:
a switch having a turning-on velocity and a first terminal electrically connected to a first voltage source providing a relatively high voltage;
a voltage-dividing circuit having a first terminal electrically connected to a second terminal of said switch and a second terminal electrically connected to a second voltage source providing a relatively low voltage;
an operational amplifier having an output terminal electrically connected to a controlling terminal of said switch, a noninverting input terminal and an inverting input terminal coupled to said voltage-dividing circuit; and
a second capacitor having a first terminal coupled to said inverting input terminal and said voltage-dividing circuit, and a second terminal electrically connected to said second voltage source;
wherein said charging velocity is controlled by adjusting said turning-on velocity of said switch with said operational amplifier while said sound source amplifier is turned on.

2. The biasing circuit as claimed in claim 1, wherein said sound source amplifier has an input terminal electrically connected to a sound source input circuit.

3. The biasing circuit as claimed in claim 2, wherein said sound source input circuit comprises a third capacitor connected to a sound input signal source in series.

4. The biasing circuit as claimed in claim 1, wherein said voltage-dividing circuit is used for providing a DC biased voltage to said sound source amplifier.

5. The biasing circuit as claimed in claim 1, wherein said first capacitor is electrically connected to a load and said load is a headphone.

6. The biasing circuit as claimed in claim 1, wherein said first capacitor is electrically connected to a load and said load is a speaker.

7. The biasing circuit as claimed in claim 1, wherein said switch is a MOSFET.

8. The biasing circuit as claimed in claim 1, wherein said first voltage source is a DC voltage source and said second voltage source is grounded.

9. The biasing circuit as claimed in claim 1, wherein said first voltage source is a DC voltage source and said relatively low voltage is a negative voltage.

10. The biasing circuit as claimed in claim 1, wherein said voltage-dividing circuit comprises a plurality of equivalent resistors.

11. The biasing circuit as claimed in claim 10, wherein said voltage-dividing circuit comprises four resistors which are connected to one another in series.

12. A biasing circuit for a sound source amplifier, wherein said sound source amplifier has an output terminal electrically connected to a first capacitor with a charging velocity, comprising:
a switch having a first terminal electrically connected to a first voltage source providing a relatively high voltage;
an operational amplifier having an output terminal electrically connected to a controlling terminal of said switch;
a first, a second, a third and a fourth resistors, wherein said first resistor has a first terminal electrically connected to a second terminal of said switch, said first resistor has a second terminal sequentially connected to said second resistor, said third resistor and a second voltage source providing a relatively low voltage in series, a first terminal of said fourth resistor is electrically connected to a node between said first resistor and said second resistor, a second terminal of said fourth resistor is electrically connected to an inverting input terminal of said operational amplifier and a second capacitor, and a noninverting input terminal of said operational amplifier is electrically connected to a node between said second resistor and said third resistor; and
a second capacitor having a first terminal coupled to said inverting input terminal and said voltage-dividing circuit, and a second terminal electrically connected to said second voltage source;
wherein said charging velocity is controlled by adjusting a turning-on velocity of said switch with said operational amplifier while said sound source amplifier is turned on.

13. The biasing circuit as claimed in claim 12, wherein said sound source amplifier has an input terminal electrically connected to a sound source input circuit.

14. The biasing circuit as claimed in claim 13, wherein said sound source input circuit comprises a third capacitor connected to a sound input signal source in series.

15. The biasing circuit as claimed in claim 12, wherein said voltage-dividing circuit is used for providing a DC biased voltage to said sound source amplifier.

16. The biasing circuit as claimed in claim 12, wherein said first capacitor is electrically connected to a load and said load is a headphone.

17. The biasing circuit as claimed in claim 12, wherein said first capacitor is electrically connected to a load and said load is a speaker.

18. The biasing circuit as claimed in claim 12, wherein said switch is a MOSFET.

19. The biasing circuit as claimed in claim 12, wherein said first voltage source is a DC voltage source and said second voltage source is grounded.

20. The biasing circuit as claimed in claim 12, wherein said first voltage source is a DC voltage source and said relatively low voltage is a negative voltage.
